(19) United States
(12) Patent Application Publication
(10) Pub. No.: US 2025/0075366 A1
(43) Pub. Date: Mar. 6, 2025

(54) SUPPORTING ROD FOR SINGLE CRYSTAL FURNACE AND SINGLE CRYSTAL FURNACE

(71) Applicant: TCL ZHONGHUAN RENEWABLE ENERGY TECHNOLOGY CO., LTD., Tianjin (CN)

(72) Inventors: Jianlong WANG, Tianjin (CN); Jian XU, Tianjin (CN); Jianping WANG, Tianjin (CN); Lin WANG, Tianjin (CN)

(73) Assignee: TCL ZHONGHUAN RENEWABLE ENERGY TECHNOLOGY CO., LTD., Tianjin (CN)

(21) Appl. No.: 18/553,509

(22) PCT Filed: Jun. 29, 2023
(86) PCT No.: PCT/CN2023/103880

§ 371 Date: Sep. 29, 2023

(30) Foreign Application Priority Data
Jul. 18, 2022 (CN) 202221852911.3

(51) Int. Cl. C30B 15/10; C30B 29/06

(52) U.S. Cl. CPC C30B 15/10; C30B 29/06

(57) ABSTRACT

A supporting rod for single crystal furnace and a single crystal furnace are provided. The supporting rod for single crystal furnace includes a rod portion, and a cone head provided at a bottom rod portion. A planar portion is provided at where the cone head is connected with the rod portion, the cone head is completely inserted into a conical hole at a top of a crucible shaft, and the planar portion is in contact with a top edge of the crucible shaft.

### CROSS-REFERENCE TO RELATED DISCLOSURE

This application claims priority to Chinese Patent Application No. 202221852911.3, filed Jul. 18, 2022, titled “SUPPORTING ROD FOR SINGLE CRYSTAL FURNACE AND SINGLE CRYSTAL FURNACE”, which is incorporated herein by reference in its entirety.

### TECHNICAL FIELD

The present disclosure relates to a technical field of a single crystal production, and particularly relates to a supporting rod for single crystal furnace and a single crystal furnace.

### BACKGROUND

With production of a single crystal silicon, various processes of the Czochralski method are increasingly improved. Currently, a single crystal furnace plays a main role on producing the single crystal silicon by the Czochralski method. The single crystal furnace mainly includes a furnace cavity, a quartz crucible, a crucible tray, a supporting rod, and a crucible shaft. The quartz crucible is provided in the furnace cavity and is used for heating material to be made into the single crystal. The crucible tray is provided in the furnace cavity and is used for supporting the quartz crucible. An upper portion of the supporting rod is disposed in the furnace cavity and is connected to the crucible tray, and a lower portion of the supporting rod is connected to the crucible shaft at a bottom of the furnace cavity.

### SUMMARY

A supporting rod for single crystal furnace is provided, which effectively alleviates a problem that a cone head at a bottom of the supporting rod is easily broken.

According to the present disclosure, a supporting rod for single crystal furnace includes a rod portion, and a cone head provided at a bottom rod portion, wherein a planar portion is provided at where the cone head is connected with the rod portion, the cone head is completely inserted into a conical hole at a top of a crucible shaft, and the planar portion is in contact with a top edge of the crucible shaft.

In an embodiment, a maximum diameter of the cone head is less than a diameter of the rod portion, and the planar portion is defined by a difference between the maximum diameter of the cone head and the diameter of the rod portion.

In an embodiment, a flange is provided at where the cone head is connected with the rod portion, and the planar portion is defined by a bottom of the flange.

In an embodiment, a vertical portion is provided between the planar portion and the cone head.

In an embodiment, a fillet is provided between the planar portion and the vertical portion.

In an embodiment, a groove is provided on a conical surface of the cone head, and the groove is extended along a generatrix of the conical surface.

In an embodiment, a plurality of the grooves are provided on the conical surface of the cone head.

In an embodiment, the plurality of grooves are uniformly distributed on the conical surface of the cone head.

In an embodiment, the rod portion is T-shaped, and a stepped hole is provided in the rod portion along an axis of the rod portion.

The single crystal furnace according to the present disclosure includes the supporting rod as described above.

By providing the supporting rod according to the present disclosure, the contact area between the cone head of the supporting rod and the crucible shaft is increased, the risk of crack of the cone head at the bottom of the supporting rod is reduced, the service life of the supporting rod is prolonged, and the production cost is reduced.

### BRIEF DESCRIPTION OF THE DRAWINGS

In order to make the embodiments of the present disclosure or the technical solutions in the prior art more clearly, reference will now be made to the accompanying drawings used in the description of the embodiments or the prior art, and it will be apparent that the accompanying drawings in the description below are merely some of the embodiments of the present disclosure, and other drawings may be made to those skilled in the art without any inventive effort.

FIG. 1 is a schematic diagram of a connection between a bottom of a supporting rod and a top of a crucible shaft according to prior art.

FIG. 2 is a schematic structural diagram of a supporting rod for single crystal furnace according to an embodiment of the present disclosure.

FIG. 3 is a schematic diagram of a connection between a cone head and a crucible shaft according to an embodiment of the present disclosure.

FIG. 4 is a schematic structural diagram of a supporting rod for single crystal furnace according to another embodiment of the present disclosure.

FIG. 5 is a schematic diagram of a connection between a cone head and a crucible shaft according to another embodiment of the present disclosure.

reference numerals:

| | | |
|---|---|---|
| 1. rod portion | 2. cone head | 3. planar portion |
| 4. vertical portion | 5. fillet | 6. exhaust hole |
| 7. first step hole | 8. second step hole | 9. third step hole |
| 10. flange | 11. crucible shaft | 12. groove |
| 13. conical hole | 14. top edge | |
| 1′. rod portion | 2′. cone head | 11′. planar portion |
| in prior | in prior | in prior |

### DETAILED DESCRIPTION OF THE EMBODIMENTS

In order that the above objects, features and advantages of the present disclosure may be more readily understood, reference will now be made in detail to the accompanying drawings. In the following description, numerous specific details are set forth in order to facilitate a thorough understanding of the present disclosure. However, the present disclosure can be practiced in many other ways than those described herein, and those skilled in the art can make similar modifications without departing from the spirit of the present disclosure, and thus the present disclosure is not limited to the specific embodiments disclosed below.

In the description of this disclosure, it should be understood that the azimuth or positional relationship indicated by the terms “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, “axial”, “radial”, “circumferential”, and the like, is based on the azimuth or positional relationship shown in the accompanying drawings, merely for ease of description of this disclosure and simplification of the description, and is not intended to indicate or imply that the indicated device or element must have a particular azimuth, be constructed and operated in a particular azimuth, and therefore is not to be construed as limiting of this disclosure.

Furthermore, the terms “first” and “second” are used for descriptive purposes only and are not to be construed as indicating or implying relative importance or implying the number of indicated technical features. Thus, the features with “first” and “second” indicate or imply to have at least one of these features. In the description herein, “a plurality of” means at least two, e.g., two, three, etc., unless expressly and specifically defined otherwise.

In the present disclosure, unless expressly defined and defined otherwise, terms such as “mounted”, “linked”, “connected”, “fixed”, and the like, should be understood as a border meaning, for example, may be fixedly connection, detachably connection, or a integrally connection; may be a mechanical connection or an electrical connection; may be a directly connection or an indirectly connection by means of an intermediate medium; and may be an internal communication of the two elements or interaction of the two elements, unless expressly defined otherwise. The specific meaning of the above terms in this disclosure may be understood by one of ordinary skill in the art depending on the specific circumstances.

In the present disclosure, unless expressly stated and defined otherwise, the first feature may be “on” or “under” the second feature may mean that the first feature directly contacts with the second feature or indirectly contacts with the second feature through an intermediate medium. And the first feature may be “over”, “above” or “up” the second feature may mean that the first feature may be directly above or obliquely above the second feature, or merely indicate that the first feature is higher than the second feature. The first feature may be “beneath”, “below” or “down” the second feature may mean that the first feature may be directly above or obliquely under the second feature, or merely indicate that the first feature is shorter than the second feature.

It should be noted that when an element is referred to as being “fixed to” or “disposed in” another element, it means that the element may be directly on another element or an intermediate element may be disposed therebetween. When an element is considered to “be connected to” another element, it means that the element may be directly connected to another element or an intermediate element may be connected therebetween. As used herein, the terms “vertical”, “horizontal”, “up”, “down”, “left”, “right”, and the like are used for purposes of illustration only and are not intended to be the only embodiments.

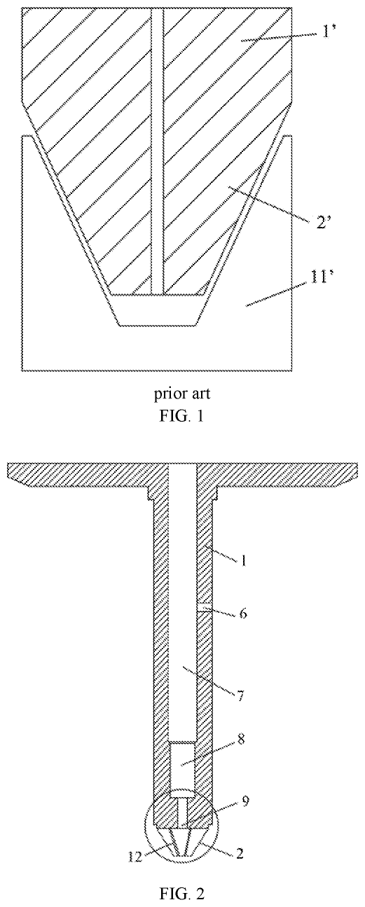

In prior art, as shown in FIG. 1, a bottom of the supporting rod 1′ is generally provided with a cone head 2′ in an inverted cone shape, and a top of the crucible shaft 11′ has an upward opening with an inner conical surface. The cone head 2′ is inserted into the upward opening of the crucible shaft 11′ for fixing. During drawing single crystal, the crucible shaft 11′ drives the quartz crucible to rotate and move up and down through the supporting rod 1′. Due to a limitation on machining accuracy, the inverted cone shape of the cone head 2′ cannot be fully fitted to the inner conical surface of the upward opening of the crucible shaft 11′. No fully contact between the cone head 2′ and the crucible shaft 11′ is provided. Since the cone head 2′ with the inverted cone shape is merely partially inserted into the top of the crucible shaft 11′, the cone head 2′ and the supporting rod 1′ are easily broken during use.

A new design of a supporting rod for single crystal furnace is provided according to an embodiment of the present disclosure, and the embodiment of the present disclosure is described below with reference to the accompanying drawings.

As shown in FIGS. 2 to 5, a supporting rod for single crystal furnace includes a rod portion 1 and a cone head 2, wherein the cone head 2 is provided at a bottom of the rod portion 1. A planar portion 3 is provided at a position where the cone head 2 is connected with the rod portion 1. The cone head 2 of the supporting rod is completely inserted into a conical hole 13 at a top of the crucible shaft 11, wherein the conical hole 13 has an inner inverted-cone surface. The planar portion 3 is in surface contact with a top edge 14 of the crucible shaft 11, thereby increasing a contact area between the cone head 2 and the top of the crucible shaft 11. The top of the crucible shaft 11 supports the supporting rod in overall to reduce a stress on the cone head 2, thereby reducing a risk of cracking the cone head 2. Material of the rod portion 1 is not limited, and may be a high-temperature-resistant material such as isostatically pressed graphite or carbon-carbon composite.

In an embodiment, a maximum diameter of the cone head 2 is less than a diameter of the rod portion 1, and a planar portion 3 is defined by a difference between the maximum diameter of the cone head 2 and the diameter of the rod portion 1. When the cone head 2 is fully inserted into the conical hole 13 of the crucible shaft 11, the cone head 2 is in a surface contact with the conical hole 13 of the crucible shaft 11, and the planar portion 3 is in a surface contact with the top edge 14 of the crucible shaft 11.

In an embodiment, the cone head 2 is provided with a flange 10 at the position where the cone head 2 is connected with the rod portion 1, so that the planar portion 3 is defined at a bottom of the flange 10. The cone head 2 is completely inserted into the conical hole 13 of the crucible shaft 11, and the bottom of the flange 10 is in surface contact with the top edge 14 of the crucible shaft 11. An outer diameter of the flange 10 is not limited herein, and may be as same as a diameter of the crucible shaft 11, or may be greater than the diameter of the crucible shaft 11, or may be less than the diameter of the crucible shaft 11, provided that the bottom of the flange 10 is in contact with the top edge 14 of the crucible shaft 11.

In an embodiment, a vertical portion 4 is provided between the planar portion 3 and a conical surface of the cone head 2, to avoid a jamming when the cone head 2 is in full contact with the crucible shaft 11. Meanwhile, in order not to affect a contact area between the conical surface of the cone head 2 and the conical hole 13 of the crucible shaft 11, a length of the vertical portion 4 is not provided too long.

In an embodiment, a fillet 5 or a chamfer is provided between the planar portion 3 and the vertical portion 4 to eliminate a stress at where the planar portion 3 is connected with the vertical portion 4 and to avoid a crack at where the rod portion 1 is connected with the cone head 2. An angle of the fillet 5 or a chamfer may be 45 degrees.

In an embodiment, a groove 12 is provided at the conical surface of the cone head 2 to avoid that the conical surface of the cone head 2 is completely stuck with the conical hole 13 of the crucible shaft 11. The groove 12 is extended along the generatrix of the conical surface of the cone head 2.

In an embodiment, a plurality of grooves 12 are provided on the conical surface of the cone head 2, and the specific number of the grooves 12 is not limited.

In an embodiment, the grooves 12 are evenly distributed on the conical surface of the conical head 2 to clamp the cone head 2 evenly.

In an embodiment, the rod portion 1 has a T-shaped structure, and a stepped hole is provided in the rod portion 1 along an axis of the rod portion 1.

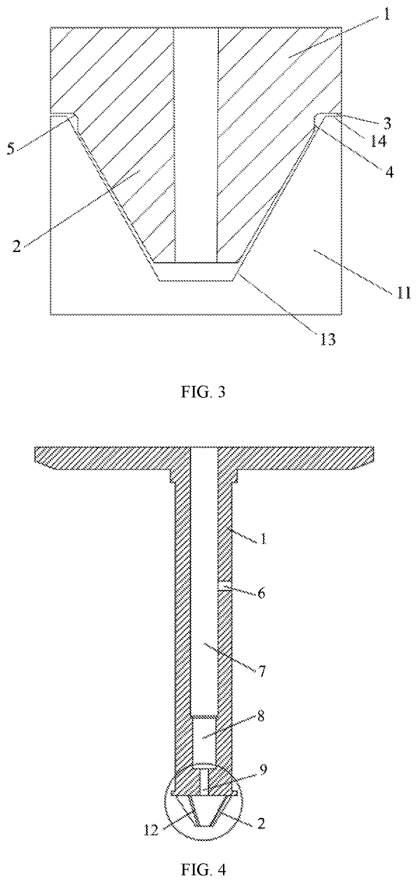

As shown in FIGS. 2 and 3, a supporting rod for single crystal furnace includes a rod portion 1 having a T-shaped structure, a first step hole 7, a second step hole 8, and a third step hole 9, wherein the first step hole 7, the second step hole 8, and the third step hole 9 are provided along an axis of the rod portion 1. A diameter of the first step hole 7 is greater than a diameter of the second step hole 8, and the diameter of the second step hole 8 is greater than a diameter of the third step hole 9. An exhaust hole 6 is provided in a wall of the first step hole 7, and the exhaust hole 6 is extended perpendicular to the axis of the rod portion 1. A cone head 2 is provided at a bottom of the rod portion 1, a diameter of the rod portion 1 is as same as a diameter of the crucible shaft 11, and a maximum diameter of the cone head 2 is less than the diameter of the rod portion 1. A planar portion 3 is provided by a difference between the maximum diameter of the cone head 2 and the diameter of the rod portion 1. A vertical portion 4 is provided between the planar portion 3 and the conical surface of the cone head 2. A fillet 5 is provided between the planar portion 3 and the vertical portion 4. The conical surface of the cone head 2 are provided five grooves 12 evenly distributed along the generatrix of the conical surface. In this embodiment, the material of the supporting rod in overall is isostatically pressed graphite.

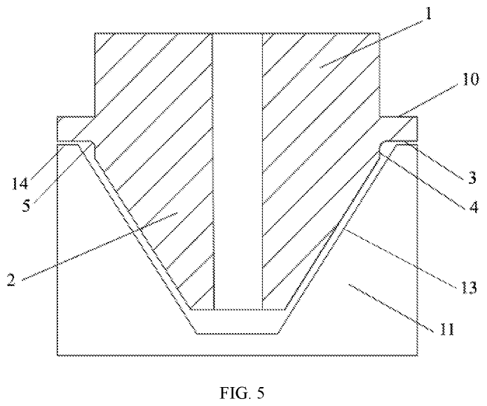

As shown in FIGS. 4 and 5, a supporting rod for single crystal furnace includes a rod portion 1 having a T-shaped structure, a first step hole 7, a second step hole 8, and a third step hole 9, wherein the first step hole 7, the second step hole 8, and the third step hole 9 are provided along an axis of the rod portion 1. A diameter of the first step hole 7 is greater than a diameter of the second step hole 8, and the diameter of the second step hole 8 is greater than a diameter of the third step hole 9. An exhaust hole 6 is provided in a wall of the first step hole 7, and the exhaust hole 6 is extended perpendicular to the axis of the rod portion 1. A cone head 2 is provided at a bottom of the rod portion 1, and a maximum diameter of the cone head 2 is as same as a diameter of the rod portion 1. A flange 10 is provided at where the cone head 2 is connected with the rod portion 1, the diameter of the rod portion 1 is less than a diameter of the crucible shaft 11, and an outer diameter of the flange 10 is equal to the diameter of the crucible shaft 11. A planar portion 3 is defined at the bottom of the flange 10, and a vertical portion 4 is provided between the planar portion 3 and the conical surface of the cone head 2. A fillet 5 is provided between the planar portion 3 and the vertical portion 4. The conical surface of the cone head 2 are provided three grooves 12 evenly distributed along the generatrix of the conical surface. In this embodiment, the material of the supporting rod in overall is carbon-carbon composite material.

According to the present disclosure, the planar portion 3 is provided at where the rod portion 1 is connected with the cone head 2. When the cone head 2 is completely inserted into the conical hole 13 at the top of the crucible shaft 11, the cone head 2 is in a surface contact with the conical hole 13 of the crucible shaft 11, and the planar portion 3 is in a surface contact with the top edge 14 of the crucible shaft 11. The rod portion 1 is supported by the top of the crucible shaft 11, thereby reducing the stress on the cone head 2. At the same time, the cone head 2 is completely inserted into the conical hole 13 of the crucible shaft 11 to increase an area of the cone head 2 receiving the stress, thereby preventing the cone head 2 from being broken due to the excessive stress exerted on the cone head 2. Since the cone head 2 is completely inserted into the conical hole of the crucible shaft 11, the vertical portion 4 and the groove 12 are provided to prevent the cone head 2 from being stuck in the conical hole 13 at the top of the crucible shaft 11. The cone head 2 is prevented from cracking, the service life of the supporting rod is prolonged, and the production cost is reduced.

A single crystal furnace is provided in the present disclosure, and the single crystal furnace includes a furnace cavity, a quartz crucible, a crucible tray, a crucible shaft 11, and a supporting rod as described above. The quartz crucible is installed in the furnace cavity, the crucible tray is installed at the bottom of the quartz crucible, the upper portion of the supporting rod supports the bottom of the crucible tray, and the lower portion of the supporting rod is connected to the crucible shaft 11. The top of the crucible shaft 11 has a conical hole 13, and the conical hole 13 has an inner inverted-cone surface. The conical head 2 of the supporting rod is completely inserted into the conical hole 13 of the crucible shaft 11. The top edge 14 of the crucible shaft 11 supports the planar portion 3 at where the rod portion 1 is connected with the conical head 2. As such, the supporting rod and the crucible shaft 11 are connected closely. The crucible shaft 11 drives the quartz crucible to rotate and move up and down through the supporting rod.

The embodiments of the present disclosure have been described in detail above, but the description is only a preferred embodiment of the present disclosure and should not be considered as limiting the scope of implementation of the present disclosure. All equivalents and modifications made in accordance with the scope of the present disclosure is within the scope of the patent of the present disclosure.

What is claimed is:

1. A supporting rod for single crystal furnace, comprising a rod portion, and a cone head provided at a bottom rod portion, wherein a planar portion is provided at where the cone head is connected with the rod portion, the cone head is completely inserted into a conical hole at a top of a crucible shaft, and the planar portion is in contact with a top edge of the crucible shaft.

2. The supporting rod for single crystal furnace of claim 1, wherein a maximum diameter of the cone head is less than a diameter of the rod portion, and the planar portion is defined by a difference between the maximum diameter of the cone head and the diameter of the rod portion.

3. The supporting rod for single crystal furnace of claim 1, wherein a flange is provided at where the cone head is connected with the rod portion, and the planar portion is defined by a bottom of the flange.

4. The supporting rod for single crystal furnace of claim 1, wherein a vertical portion is provided between the planar portion and the cone head.

5. The supporting rod for single crystal furnace of claim 2, wherein a vertical portion is provided between the planar portion and the cone head.

6. The supporting rod for single crystal furnace of claim 3, wherein a vertical portion is provided between the planar portion and the cone head.

7. The supporting rod for single crystal furnace of claim 4, wherein a fillet is provided between the planar portion and the vertical portion.

8. The supporting rod for single crystal furnace of claim 1, wherein a groove is provided on a conical surface of the cone head, and the groove is extended along a generatrix of the conical surface.

9. The supporting rod for single crystal furnace of claim 2, wherein a groove is provided on a conical surface of the cone head, and the groove is extended along a generatrix of the conical surface.

10. The supporting rod for single crystal furnace of claim 3, wherein a groove is provided on a conical surface of the cone head, and the groove is extended along a generatrix of the conical surface.

11. The supporting rod for single crystal furnace of claim 7, wherein a groove is provided on a conical surface of the cone head, and the groove is extended along a generatrix of the conical surface.

12. The supporting rod for single crystal furnace of claim 8, wherein a plurality of the grooves are provided on the conical surface of the cone head.

13. The supporting rod for single crystal furnace of claim 12, wherein the plurality of grooves are uniformly distributed on the conical surface of the cone head.

14. The supporting rod for single crystal furnace of claim 1, wherein the rod portion is T-shaped, and a stepped hole is provided in the rod portion along an axis of the rod portion.

15. The supporting rod for single crystal furnace of claim 2, wherein the rod portion is T-shaped, and a stepped hole is provided in the rod portion along an axis of the rod portion.

16. The supporting rod for single crystal furnace of claim 3, wherein the rod portion is T-shaped, and a stepped hole is provided in the rod portion along an axis of the rod portion.

17. The supporting rod for single crystal furnace of claim 7, wherein the rod portion is T-shaped, and a stepped hole is provided in the rod portion along an axis of the rod portion.

18. The supporting rod for single crystal furnace of claim 12, wherein the rod portion is T-shaped, and a stepped hole is provided in the rod portion along an axis of the rod portion.

19. A supporting rod for single crystal furnace of claim 13, wherein the rod portion is T-shaped, and a stepped hole is provided in the rod portion along an axis of the rod portion.

20. A single crystal furnace, comprising the supporting rod for single crystal furnace of claim 1.
